(19) United States
(12) Patent Application Publication
(10) Pub. No.: US 2002/0182877 A1
(43) Pub. Date: Dec. 5, 2002

(54) Photo-processing of materials in the presence of reactive fluid

(76) Inventors: Marc Nantel, Oakville (CA); Yuri Yashkir, Oakville (CA)

Correspondence Address: DOWELL & DOWELL PC, SUITE 309, 1215 JEFFERSON DAVIS HIGHWAY, ARLINGTON, VA, 22202

(21) Appl. No.: 10/118,339

(22) Filed: Apr. 9, 2002

Related U.S. Application Data
(60) Provisional application No. 60/282,196, filed on Apr. 9, 2001.

(51) Int. Cl. H01L 21/00; B44C 1/22

(52) U.S. Cl. 438/708; 216/62; 156/74

(57) ABSTRACT

The present Invention provides a method of photo-processing of materials in the presence of a reactive fluid which involves using light selected on the basis that the material has a long absorption for the wavelength of emission of the light. The present invention teaches photo-processing of semiconductors such as silicon using infrared radiation and is very advantageous since, in those materials to be processed having a very long absorption for the wavelength of emission of the light, one obtains volume absorption deep under the surface of the illuminated region so that the material under the surface is heated. The material is irradiated with the light beam in the presence of a reactive gas, the light beam having a wavelength in an infrared portion of the electromagnetic spectrum wherein the irradiated selected region of the solid is heated and reacts with the reactive gas to remove atoms or molecules of the material from the irradiated region.

### CROSS REFERENCE TO RELATED UNITED STATES PATENT APPLICATION

This patent application relates to United States Provisional patent application Serial No, 601282,196 filed on Apr. 9, 2001, entitled INFRARED LASER MACHINING OF MATERIALS.

### FIELD OF THE INVENTION

The present invention relates to a method of processing of materials using light, and more particularly the present method relates to processing of semiconductors such as silicon using infrared light in the presence of a reactive fluid.

### BACKGROUND OF THE INVENTION

Photo-processing of materials, such as laser micromachining, is a technique that offers precise, non-contact and accurate machining of very small components, and is an emerging advanced manufacturing technology that is being adapted to widely diverse industrial applications. Conventional mechanical machining can produce work-pieces and assemblies with typical feature sizes larger than a few hundred microns. However, the steadily increasing demand for smaller sizes requires new tools and processes, of which laser micromachining is one example.

Machining of materials such as silicon in the presence of a halogen or halogen-containing gases is well known. The paper T. F. Deutsch, D. J. Ehrlich, R. M. Osgood, Jr., Journal of Applied Physics, Vol. 38, Number 12 (Jun. 15, 1981), Laser Chemical Technique for Rapid Direct Writing of Surface Relief in Silicon discloses a laser machining system using a 7-W argon ion laser with 1-500 Torr of Cl₂ or HCI. Using 7 W of power of visible light, 200 Torr Cl₂ and a scan speed of 4.4 mm/s the author was able to etch a groove of depth 3.9 μm. These studies also showed that the groove depth is not linearly proportional to the laser dwell time, in fact it increases more slowly than if it were a linear dependence. By allowing the laser spot to remain in place for 35-45s, the authors were able to etch a conical hole through a wafer of thickness 250 μm. The diameter of the topside of the hole measured 40 μm and the underside diameter was 15 μm. The authors also tested whether or not the oxide layer formed on the wafer had any significant effect. There tests showed that they could achieve higher etching rates and use higher scan speeds only if they removed the oxide by first cleaning the wafer with HF. The authors conclude the two following regimes for etching: below the melting point the etching is faster and is greatly accelerated by the photo-dissociation of the etchant, and near or above the melting point the gas phase photo-dissociation no longer effectively accelerates the reaction.

The paper K. W. Beeson and V. H. Houlding, Journal of Appl. Phys., Vol. 64, Issue 2, pp. 835-840 (1988), Laser Etching of LiNbO₃ In a Cl₂ atmosphere, discloses laser etching of LiNbO₃ in chlorine using a frequency doubled CW argon-ion laser at a wavelength of 257 nm.

The paper W. Sesselmann, E. Hudeczek. and F. Bachmann, Journal of Vacuum Science & Technology B: Microelectronics and Nanometer Structures, Vol. 7, Issue 5, pp. 1284-1294 (1989), Reaction of silicon and ultraviolet laser induced chemical etching mechanisms, studies the reaction mechanism of chlorine with silicon during excimer laser-induced chemical etching using 308 nm and 248 nm. These results show that under these conditions, a thin passivating chlorinated surface layer is built up which impedes further reaction.

The publication by T. M. Bloomstein and D. J. Ehrlich, Journal of Applied Physics, Vol. 61, Number 6, Aug. 10, 1992, Stereo Laser Machining of Silicon, discloses a laser machining system employing a cw argon laser, λ=488 nm (circular polarization) with the beam deflected by using TeO₂ acousto-optic deflectors atν=102 MHz. As a result, the beam is split into a 256 ×256 pixel array with the capability of accessing each pixel. Spot size was approximately 1 μm. Chlorine gas was allowed to flow over the surface. At a pressure of 100 Torr, power of 900 mW and feed rate approximately 7 mm/s, the authors were able to produce the article shown In FIG. 1 of the publication. The authors also achieved a removal rate of 2.0 ×10⁴ μm³ by using 400 Torr of chlorine. According to the article the removal rate weakly depended on the power and the feed rate. However, they achieved higher etch rates by using higher pressure and increasing the spot size. Their explanation for the reaction is that the silicon at the focused laser spot is heated just to its melting point, and the melted material is removed by the chlorine gas producing SiCl₂ and SiCl₄. disclosed Laser Micromachining of Silicon: A New Technology for Fabricating THz Imaging Arrays, which uses a system including a cw 15 W Argon-Ion Laser operating atλ=488nm with the beam circularly polarized to produce better edge quality. A pair of computer-controlled galvanometers was used to deflect the beam in the xy plane to produce a 256 ×256 field of pixels. They could address each pixel at two speeds; random at 5 ×10⁴ pixels/s or in raster mode at a speed of 2.5 ×10⁶ pixels/s. Machining was carried out in a controlled chlorine gas environment. Using 4.3 W, a 6-μm spot, 200 Torr of chlorine gas with a can speed of 5 cm/s the authors were able to etch an 810-GHz feedhorn. The total machining time was one hour. Each pass of the laser removed approximately 1-μm shavings, and a 2-μm separation was set between each scan. A 2-THz waveguide structure was machined using 2 W of power, 200 Torr of chlorine, and a focused spot size of 4 μm. The scan speed was set at 4 cm/s with a separation between each pass of 2 μm. Each scan shaved off 0.65 μm of material.

H. Dirac, M. Mullenborn, J. W. Petersen, Journal of Applied Physics, Vol. 66, Number 22 (May 29, 1995), Silicon Structures Produced by Laser Direct Etching discloses a laser machining system using a continuous wave (cw) argon laser operating at λ=488 nm with an acousto-optical modulator to control intensity. In this publication, the authors' main approach to studying this reaction is by examining the heat problem given by∇[χ∇T ]=Q. Their analysis basically leads to the idea that the melt zone should be limited to just the spot size, and just melted. Their study also shows that the smaller the spot size the better etching, but due to mechanical problems the ideal region could not be reached by the authors.

The paper by D. Fowlkes, D. H. Lowndes, A. J. Pedraza, Journal of Applied Physics, Vol. 77, Number, 11 (Sep. 11, 2000), Microstructural Evolution of Laser-Exposed Silicon in SF₆, discloses a laser machining system using a nanosecond pulsed excimer laser atλ=248 nm with a fluence of 3 J/cm², with the laser machining carried out in the presence of SF₆. This publication provides an explanation about the formation of microholes and microspikes by investigating how pressure and the number of pulses affects growth rates. The fluence was kept constant throughout their experiments, at 3 J/cm².

U.S. Pat. No. 4,260,649 issued to Dension et al. is directed to a method and apparatus for chemical treatment of workpieces in which the workpiece is exposed to a controlled gaseous atmosphere containing a gas which is dissociated by laser radiation to produce a gaseous reactant product for reaction with the surface of the workpiece. The wavelength of the laser beam radiation is selected for splitting only the desired bonds to produce only the desired reactant product without producing undesired by-products which could deleteriously interfere with the desired chemical reaction.

U.S. Pat. No. 4,622,095 issued to Grobman et al. teaches a method of radiation induced dry etching of a metallized (e.g. copper) substrate in which the substrate is pattern-wise exposed to a beam of laser radiation in a halogen gas atmosphere that is reactive with the substrate to form a metal halide salt reaction product to accelerate the formation of the metal halide salt without its substantial removal from the substrate. The metal halide salt is subsequently removed from the substrate by contact of the substrate with a solvent for the metal halide salt.

U.S. Pat. No. 4,751,779, by Nagatomo et al. teaches a core for a magnetic head, which has a surface roughness of not higher than 2 μm in the side wall of a groove for defining the track width of the core, can be obtained by subjecting at least a portion, which defines the track width, of a gapped bar made of ferrite and having a coil turn hole and a magnetic gap, to a laser-induced etching under a condition that a laser light having a power of 50-1.100 mW and a focused beam diameter of not larger than 20 μm is irradiated to at least the track width-defining portion at a scanning speed of 2-110 μrm/sec in a halogen gas- or halide gas-containing atmosphere kept to a gas pressure of 10-200 Torr.

U.S. Pat. No. 4,834,834 issued to Ehrlich et al. is directed to a method for maskless patterning and etching of metals. A passivating layer of an oxide or nitride is formed on the surface of the metal which is then exposed to a halogenous atmosphere, while patterning the metal is achieved using a directed energy beam to selectively replace the oxides or nitrides with halides, and heating the patterned metal while exposing it to an etchant to etch regions located below the halogenated surfaces leaving the remaining passivated regions intact.

U.S. Pat. No. 5,389,196 issued to Bloomstein et al. discloses a light-based method for producing a three-dimensional object. The beam is directed to selectively expose a pattern of address points on the interface plane to the beam of radiant energy for a limited time. Conditions are established in the chamber to enable the beam to induce a micro-chemical reaction at the interface plane at a rate which serves to form a portion of the three-dimensional object. The micro-chemical reaction is essentially binary with respect to the beam energy density so that the reaction is either “on” or “off.”

U.S. Pat. No. 5,874,011 issued to Ehrlich teaches techniques and an apparatus for the laser induced etching of a reactive material, or of a multilayer substrate or wafer comprising layers of materials of different etching characteristics and reactivities. Short wavelength laser radiation is used and controlling the gas is used to equalize etch rates of the layers of a multilayer substrate for high-resolution etching. For less reactive layers or materials, reduced-pressure air is a suitable ambient. The techniques and apparatus disclosed herein are particularly useful in the manufacture of magnetic data transfer heads,

It would be very advantageous to provide a method of photo-processing materials, using for example lasers, that provides a much more efficient way for processing the materials than presently available with visible and UV lasers. Also, it would be advantageous to provide a laser machining method that uses infrared light, which is generally cheaper to produce. Finally, it would be advantageous to provide a laser machining method in which the laser could be used not only in the infrared but also to allow frequency-conversion to cover the visible and UV ranges of the spectrum, thereby providing more versatility.

### SUMMARY OF THE INVENTION

The present invention provides a method of photo-processing of materials using light beams to process or machine the material in the presence of a reactive fluid.

In one aspect of the invention there is provided a method of photo-processing a material, comprising:

illuminating a selected region of a material with a light beam in the presence of a reactive fluid, said light beam having a wavelength in an infrared portion of the electromagnetic spectrum wherein the material has a sufficiently long absorption depth at said infrared wavelength for obtaining volume absorption under the surface of the illuminated region so that the material in a volume under the surface is heated and reacts with said reactive fluid to remove atoms or molecules of said material from said selected region.

In this aspect of the invention the material being photo-processed may be a semiconductor such as silicon and the reactive fluid may be a halogen or halogen-containing gas and the light source may be a coherent laser light source

In another aspect of the invention there is provided a method of photo-processing of materials, comprising:

selecting a material to be photo-processed and selecting a light source that emits light at a wavelength for which said material has a long absorption depth for obtaining absorption in a volume region under the surface of the material for heating said volume region; and

illuminating a selected region of said material with a beam of the light in the presence of a reactive fluid, wherein said illuminated selected region of said material is heated and reacts with said reactive fluid to remove atoms or molecules of said material from said illuminated region.

In another aspect of the Invention there is provided a method of multi-wavelength photo-processing of materials, comprising:

illuminating a region of a material with a light beam of a first wavelength in the presence of a reactive fluid for a pre-selected length of time wherein said illuminated material is heated and reacts with said reactive fluid to remove atoms or molecules of said material from said illuminated region; and

illuminating a region of said material with a light beam of a second wavelength In the presence of a reactive fluid for a pre-selected length of time wherein said illuminated material is heated and reacts with said reactive fluid to remove atoms or molecules of said material from said illuminated regions, wherein at least one of said first and second wavelengths are selected on the basis of said material having a sufficiently long absorption depth for obtaining absorption in a volume region under the surface of the material for heating said volume region.

In this aspect of multi-wavelength processing a material, an infrared light beam may be used to obtain the efficient, rapid machining in the presence a reactive gas such as a halogen or halogen-containing gas. The wavelength of the light beam or laser is then switched to the visible or UV to machine finer features at a slower rate.

### BRIEF DESCRIPTION OF THE DRAWINGS

Preferred embodiments of the invention will now be described, by way of example only, with reference being had to the drawings, in which:

FIG. 1 shows a system for laser machining of materials in accordance with the present invention;

FIG. 2 shows the principle behind laser-assisted chlorine etching of silicon (here, for example, with UV light).

FIG. 3 shows plots of groove depth vs. chlorine pressure for the chlorine-assisted etching of silicon with IR laser emission at 4 mm/min feed rate, for 2.6 W, 2.8 W and 3.1 Watts of laser power;

FIG. 4 shows plots of groove depth vs. chlorine pressure for the chlorine-assisted etching of silicon with IR laser emission at 8 mm/min feed rate for 2.6 W. 2.8 W and 3.1 Watts of laser power;

FIG. 5 shows plots of groove depth vs. chlorine pressure for the chlorine-assisted etching of silicon with IR laser emission at 12 mm/min feed rate for 2.6 W, 2.8 W and 3.1 Watts of laser power;

FIG. 6 shows laser-machined groove depths vs. the number of IR laser passes showing the dependence of etching on the number of laser passes;

FIG. 7 shows photographs of features laser-machined into silicon showing the effect of chlorine assistance during the laser etching of silicon (IR power: 5 W, repetition rate: 5 kHz, feed rate: 1 mm/min, 3 passes), upper photo: chlorine pressure is 400 Torr, (groove 380 μm deep, 50 μm wide, etching rate˜106,000 μ³/sec or 21 μ³/pulse), lower photo: vacuum (groove 8 μm deep, 50-μm wide, etching rate˜2,300 μ³/sec or 0.46 μ³/pulse); approximately 9 minutes of cutting for each feature;

FIG. 8 shows results from computer simulations to illustrate qualitatively the difference between long-absorption-length light in silicon (IR) and short-absorption-length light in silicon (UV, green) with FIG. 8a) UV profile, FIG. 8b) green profile and FIG. 8c) IR profile;

FIGS. 9a,9b and 9c gives an example of features micromachined using a frequency-doubled (green) DPSS laser, each step is 20-μm wide (for FIGS. 9a and 9b: laser parameters: 9-mW of λ=526-nm light in 0.45-μJ pulses, 470-ns pulse duration, 20-kHz repetition rate, 8-μm focal spot diameter for an on-target intensity of 2 ×10⁶ W/cm², etch rate∥- 21 μm³/s; FIG. 9a taken with an optical microscope; FIG. 9b is a profile cut through the features in FIG. 9a, as measured with a white-light interferometric profilometer, for FIG. 9c: laser parameters: 50-mW ofλ=526-nm light In 2.5-μJ pulses, 450-ns pulse duration, 20-kHz repetition rate, 8-μm focal spot diameter for an on-target intensity of 1×10⁷ W/cm², etch rate˜652 μM³/s: FIG. 9c taken with an electron microscope), and

FIG. 10 gives an example of features micromachined using a frequency-tripled (UV) DPSS laser (UV power: 16 mW, repetition rate: 8 kHz, feed rate: 0.2 mm/min), chlorine pressure is 100 Torr, (trenches were machined in 1, 2, 3. 4 and 5 passes (from right to left) are 1-4 Kim deep, 5-μm wide, etching rate ˜15 μ³/sec).

### DETAILED DESCRIPTION OF THE INVENTION

The present invention for photo-processing of materials in the presence of a reactive fluid involves selecting a light source on the basis that the material being processed has a long absorption for the wavelength of emission of the light. For example, using infrared radiation to machine materials such as silicon is very advantageous since, as in other materials to be processed having a very Is long absorption for the wavelength of emission of the light, one obtains volume absorption deep under the surface of the illuminated region so that the material under the surface is heated. New hot material is then continually exposed to the reactive gas as the surface is etched away, so that reaction in the presence of a reactive gas is very efficient and continuous, giving high machining rates. In contrast, when machining with UV and visible light, most of the light is absorbed in a relatively thin region near the surface of the work-piece due to the strong absorption of and by most materials. For example, the absorption lengths for 1/e reduction of Intensity In silicon are 0.01 μm at 351-nm wavelength (ultraviolet), 0.94 μm at 534-nm wavelength (green) and 710 μm at 1,053-nm wavelength (infrared).

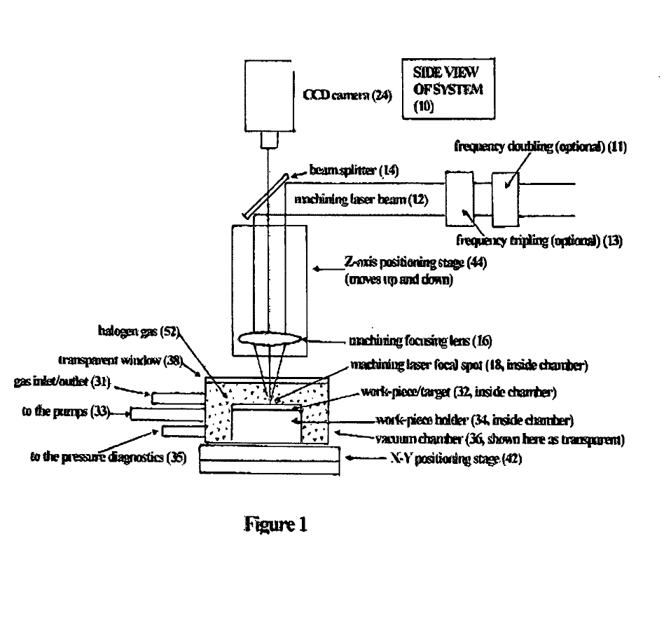

A system for laser processing materials is shown generally at 10 in FIG. 1. A sample 32 of the material to be processed is placed on holder 34 in chamber 36 that is evacuated by pumping system 33 and a halogen or halogen-containing gas 52 is admitted to the chamber through well-regulated inlet/outlet valves 31. The pressure conditions in the chamber 36 are monitored by a pressure probe 35. A light beam 12, preferably an infrared light beam, and preferably from a continuous or pulsed laser source, is directed by mirrors and beam-splitters 14 and focused by lens 16 to a focal spot 18 on a pre-selected region on the sample 32 through transparent window 38. The infrared laser beam can also optionally be frequency-doubled to green using a non-linear crystal 11 or frequency-tripled to the ultraviolet using non-linear crystals 11 and 13 in combination. The chamber 36 is mounted on an X-Y micropositioning stage 42 to allow sample 32 to be moved under the laser focal spot 18 for the machining of features on sample 32. Alternatively, the sample 32 can be fixed, but it is then the laser beam 12 that must be scanned over the surface of sample 32 to allow for the machining of features. The focusing lens 16 is fixed on a Z micropositioning stage 44 to allow focal spot 18 to move vertically to permit the machining of three-dimensional structures in sample 32. The process is monitored in real time by a charge coupled device (CCD) camera 24 and associated displays (not shown).

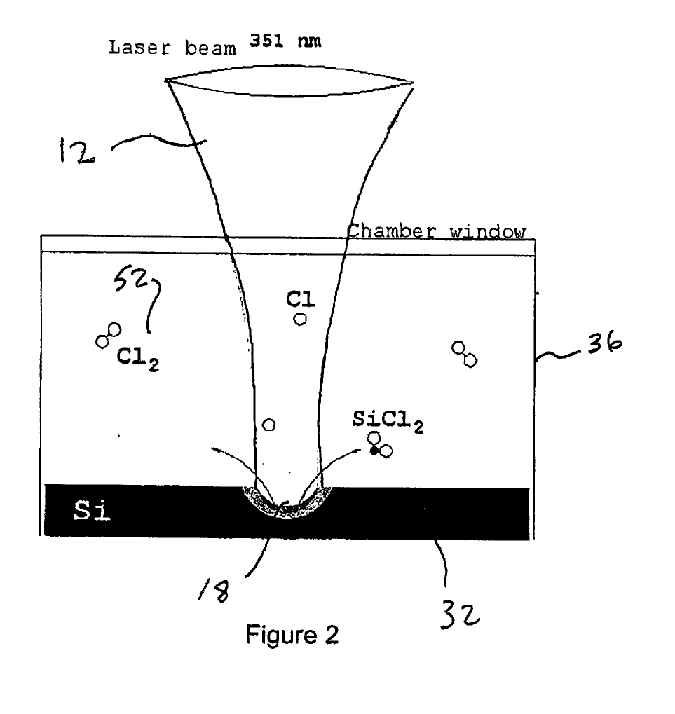

FIG. 2 shows a schematic view of the area near the light-matter interaction region, in the vacuum chamber 36 with a halogen gas 52 flowing therein. The laser beam 12 (here shown in its frequency-tripled wavelength of 351 nm) and its focal spot 18 hitting the sample 32 will raise the temperature of the sample at and below the position of the focal spot 18 through absorption of the laser light. The halogen gas 52 in the chamber 36 above sample 32 will chemically interact with the sample 32 and preferably etch away the material of the sample 32 at the higher temperature, i.e. at and below the focal spot 18. Without unduly limiting the present invention, it is contemplated that the mechanism of machining is most likely chemical etching (in the case of a silicon sample and chlorine as the halogen gas: 3Cl₂+2Si→SiCl₂+SiCl₄ and also 6Cl+2Si→SiCl₂ +SiCl₄) of the heated surface of the sample 32 in contact with the halogen gas 52. The threshold (with respect to the laser power) of this chemical reaction Is lower at higher halogen gas pressure. In the case of chlorine on silicon, for example, the exact chemical mechanism is slightly different depending on whether one uses UV light (which dissociates some of the Cl₂ molecules into atomic chlorine) or green/IR light (which is not appreciably absorbed by the chlorine gas, leaving it in its molecular form), but the result is the same: silicon Is being machined using a reaction with chlorine.

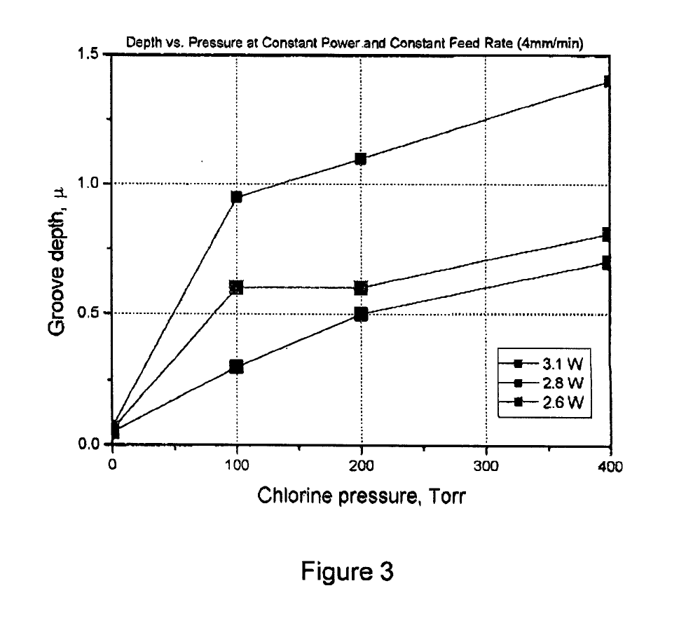

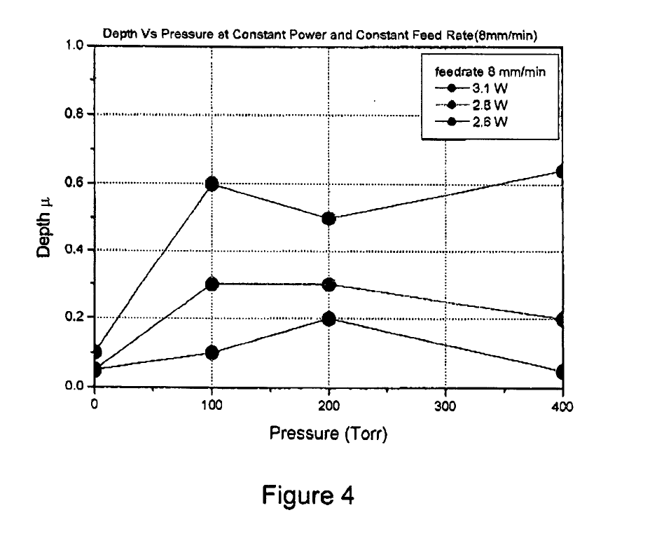

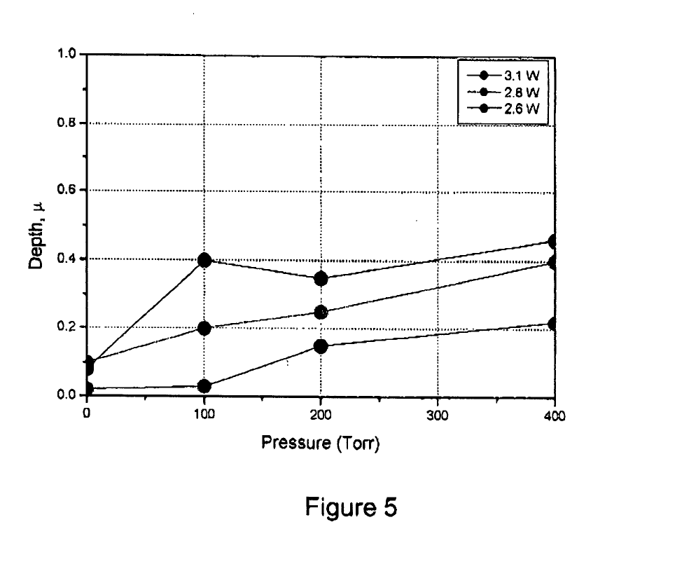

FIG. 3 shows plots of groove depth vs. chlorine pressure for chlorine-assisted etching of the silicon with IR laser emission and the sample moved at a 4 mm/min feed rate, for 2.6 W, 2.8 W and 3.1 Watts of infrared laser power (1,053-nm wavelength, at 8-kHz repetition rate and 100-ns pulse duration, focal spot diameter: 10 μm). It is noted that there Is a dramatic increase of etching rate, as chlorine becomes available (from 0 Torr to 100 Torr of chlorine pressure), and a regular increase in the etching rate as the chlorine pressure rises gradually to 400 Torr. FIG. 4 shows plots of groove depth vs. chlorine pressure for chlorine-assisted etching of the silicon with IR laser emission and the sample moved at 8 a mm/min feed rate for 2.6 W, 2.8 W and 3.1 Watts of laser power (same laser conditions as in FIG. 3). The data shown in FIG. 4 suggests that a higher feed rate leads to a lower etching rate. Note the “saturation” effect as the chlorine pressure increases. One possible explanation for this, as contemplated by the inventors, is that the faster feed rate corresponds to a shorter dwell time on any given location of the focal spot on the silicon surface, thereby resulting In a lower amount of energy absorbed and a corresponding lower temperature reached at that location; this would slow down the chemical interaction between the halogen gas and the sample to machine. FIG. 5 shows plots of groove depth vs. chlorine pressure for chlorine-assisted etching of the silicon with IR laser emission and the sample moved at a 12 mm/min feed rate for 2.6 W. 2.8 W and 3.1 Watts of laser power (same laser conditions as in FIGS. 3 and 4).

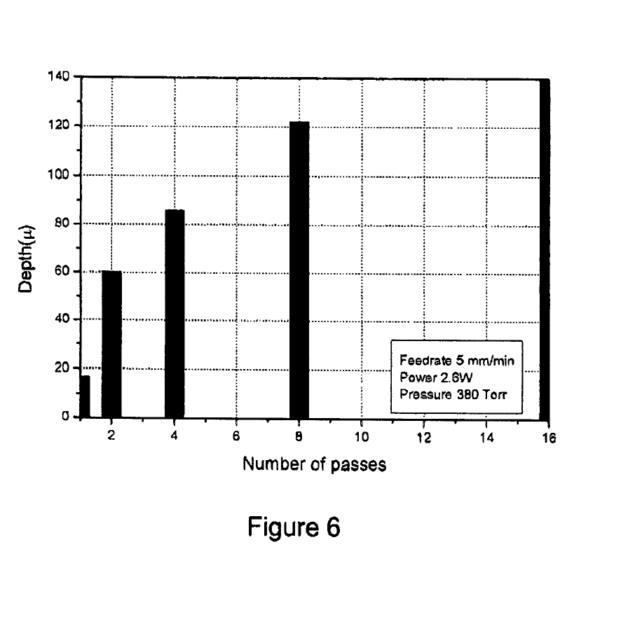

FIG. 6 shows laser-machined groove depths versus the number of laser passes, showing the dependence of etching on the number of laser passes, N. In this figure, the laser conditions are the same as those for FIGS. 3, 4 and 5, except that the pulse repetition rate was changed to 5 kHz from 8 kHz. This makes the peak power of the laser˜2 times higher, thereby increasing the etching rate significantly. The sub-linear dependence of depth vs. N can be explained (at least partially) by the defocusing of the laser beam on the active area as the depth Increases, and by the fact that the chlorine had to reach the bottom of the narrow trench to interact with the fresh heated silicon surface.

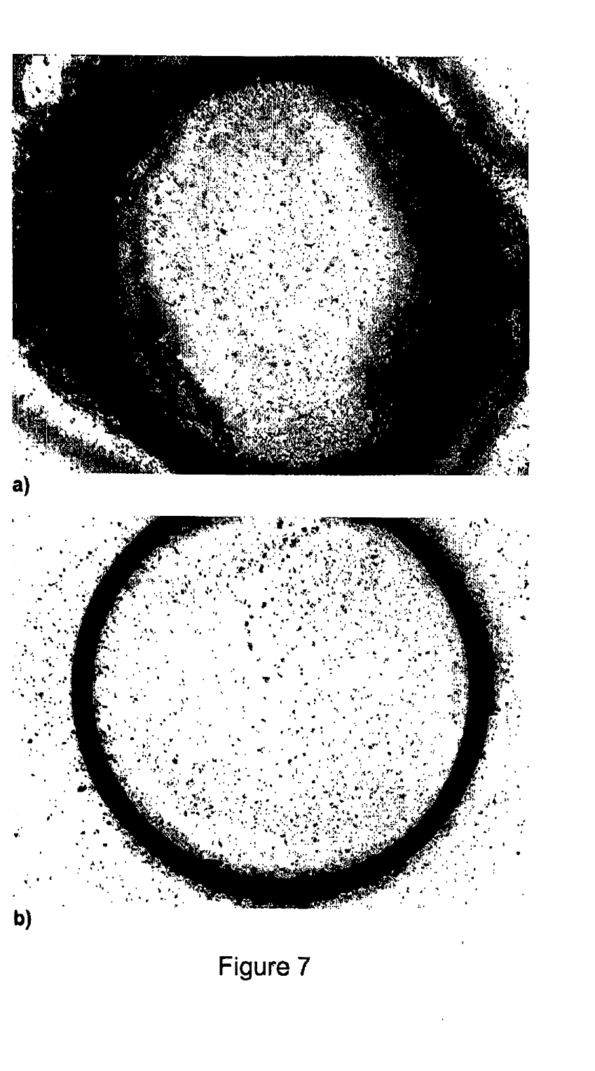

FIG. 7 shows optical microscope photographs of features laser-machined into silicon showing the effect of chlorine assistance during the laser etching of silicon with infrared light. It is a comparison of an annulus cut a) in vacuum and b) in 400 Torr of chlorine gas. The laser parameters are: 5 W of λ=1,053-nm light in 520-μJ pulses, 100-ns pulse duration, 5-kHz repetition rate, 10-μm focal spot diameter for an on-target intensity of 7 ×10⁹ W/cm². In three passes, the annulus in a) is 8-μm deep (˜2,300 μm³/s etching rate) and the one in b) is 380-μm deep (106,000μm³/s etching rate). This etching rate was obtained on the first try, without even optimizing the process. Not only is the etching rate nearly 50 times higher in the case with chlorine, but the resulting feature is much cleaner (no large “burn” marks like in FIG. 7a). For the conditions used in FIG. 7, in the absence of chlorine, the laser peak power is not sufficient to efficiently ablate silicon with the infrared radiation (it is melted, but evaporation is quite slow, explaining the low material removal rate). From the general tendency in the curves of FIGS. 3, 4 and 5 (where etching rates more than double when the laser power increases only 20% from 2.6 W to 3.1 W ), it can be inferred conservatively that rates as high as ˜300,000-500,000 μm³/s are expected to be easily obtained with a 5-kHz, 10-W pulsed IR laser beam on silicon in a chlorine atmosphere. This is 3-5 times the etching rate achieved by a state-of-the-art system powered by a much larger and much more expensive-to-run argon laser.

Using light having wavelengths in the infrared is advantageous since, in those materials to be processed having a very long absorption depth (710 μm at 1,053 nm for a 1/e intensity decrease in silicon, for example), one obtains volume absorption deep under the surface of the illuminated region so that the material under the surface is heated. New hot material is then continually exposed to chlorine when the surface evaporates so that the reaction in the presence of chlorine is very rapid and continuous. This contributes in part to the high machining rates disclosed herein when using infrared. In contrast, when machining with UV and visible, most of the light is absorbed in a relatively thin region under the surface due to the strong absorption of UV (0.01 mm at 351 nm for a 1/e intensity decrease in silicon, for example) and visible (0.94 mm at 534 nm for a 1/e intensity decrease in silicon, for example) by most materials.

It will be understood that the method of laser machining materials disclosed herein, while having been illustrated using silicon as the material, may be applied to other materials having a long absorption depth at the processing wavelength. For example, the material may be other semiconductors, e.g. germanium or gallium arsenide, or ceramics such as dielectrics or high-T_{c} superconductors, or polymer materials. The reactive gas may be a pure halogen gas such as chlorine or fluorine or it may be a halogen-containing gas. While a halogen gas or halogen-containing gas is preferred it will be appreciated that more generally a halogen fluid or halogen containing fluid in either liquid or gaseous phase may be used.

When materials other than silicon are machined the reactive gas and the processing light wavelength(s) are selected appropriately for the optical properties (i.e. absorption depth a) of the particular material being processed so that one achieves an analogous effect as achieved when photo-processing silicon with the combination of chlorine gas and IR light.

While not a limitation of this invention (any focused infrared light source would do), the photo processing light beam is preferably from a pulsed or continuous wave (cw) laser beam. A very useful laser system that could be used is a diode-pumped solid-state YLF laser which can, with the proper combination of non-linear crystals, emit in the UV and visible in addition to the infrared. A diode-pumped solid-state YAG laser, or flashlamp-pumped YLF or YAG lasers, or other doped-glass lasers emitting in the infrared would also show similar results. Advantages of diode-pumped solid-state lasers are that they are much cheaper to operate than excimer and argon-ion lasers and they give high etching rates. Diode-pumped solid-state lasers also typically require less maintenance, which makes them well suited for large-scale production work. In processing the material, one may use the infrared emission to obtain the very fast, rapid machining in the presence a reactive gas such as a halogen or halogen-containing gas. One could then switch the output emission of the laser to the visible or UV to machine finer features at a slower rate. In this way one could move along a sample and machine precise steps into the surface very quickly.

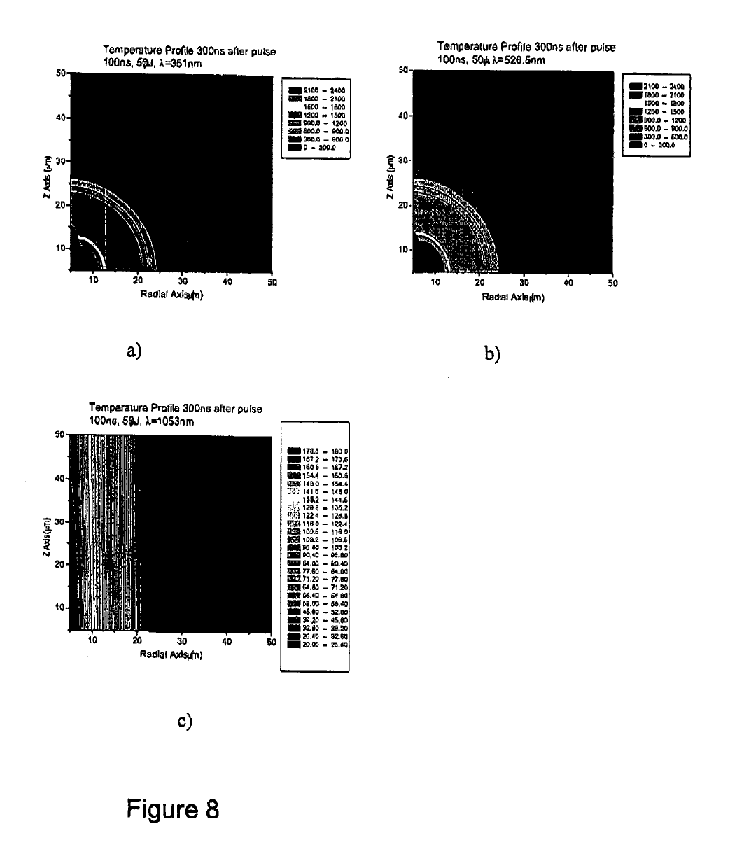

To explain this difference between infrared wavelengths on the one hand and the green and UV wavelengths on the other hand, FIGS. 8a, 8b and 8c show computer simulations of the heat diffusion expected in silicon from a laser pulse hitting the material from the bottom. Only the radial and vertical coordinates are shown, and there is a rotational symmetry about the vertical axis to obtain a full temperature profile. A qualitative agreement with our earlier statement about the heat distribution in the silicon can be seen in FIGS. 8a to 8c, where a single laser pulse was made to hit the solid silicon target. FIGS. 8a to 8c show the temperature profiles as a function of the depth into the silicon sample (vertical axis labeled “Z Axis”) and the distance from the center of the laser pulse hitting the sample (horizontal axis labeled “Radial Axis”), 300 ns after the laser pulse. All simulations are for 100-ns pulses, but FIG. 8a is for a 50-μJ UV pulse, FIG. 8b is for a 50-μJ green pulse, and FIG. 8c is for a 50-μJ IR pulse While the temperature profiles for the UV and green interactions are quite similar (FIGS. 8a and 8b), they are both quite different from those for the IR interaction for the same pulse energy (FIG. 8c) In the UV and green case, the laser energy was absorbed in thin layers near the surface of the target, thereby allowing the heat diffusion to happen in a three-dimensional fashion (in the z direction and radially), giving a characteristic hemispherical profile for the temperature gradient.

In contrast, for the IR case the energy is absorbed much more gradually through the whole thickness of the silicon target along the laser propagation axis (the z-axis). This only allows the heat diffusion to happen in a cylindrical 2-dimension fashion, as shown in Figure 8c. Due to the lower amount of energy absorbed in the target (some just goes right through it), the much larger volume over which the absorbed laser energy is distributed and the initially larger area available for the heat diffusion, the temperatures of the heated silicon for a 50-μJ IR pulse do not rise as high as for the UV and green pulses of the same energy. This is why “holes” can be seen in Figures 8a and 8b which corresponds to the dark area or removed material near the origin, while there is none in FIG. 8c. For the IR case, the temperature never got high enough for vaporization in the simulation This is partly due also to the fact that the simulations were all conducted with the same pulse energy (50 μJ) for all three wavelengths instead of the experimental case where the IR pulses are typically 10 times more energetic than the UV pulses. The simulations shown in FIG. 8 have not been exactly calibrated with the experimental results and are only shown to exemplify the heat-diffusion profiles; they are not meant to be quantitative.

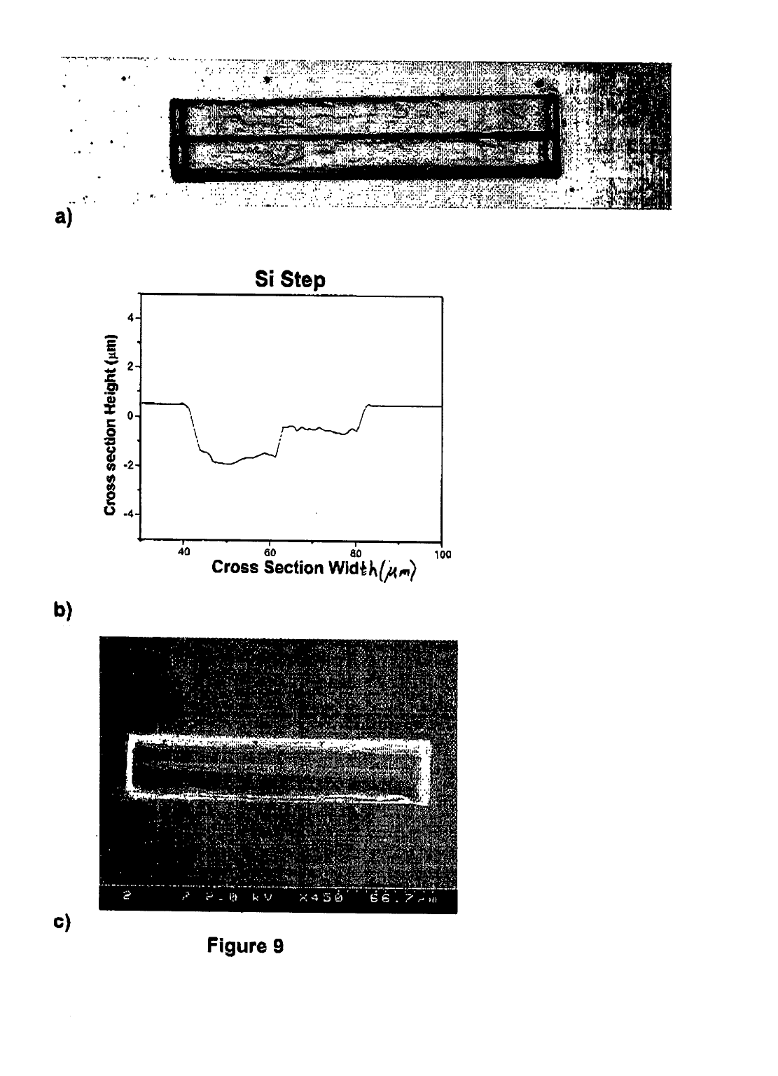

As an example of green-light micromachining using a frequency-doubled DPSS laser, FIGS. 9a, 9b and 9c show two-step features machined out of a silicon wafer in a chlorine atmosphere. FIG. 9a shows the optical microscope photograph of a two-step feature where the steps are 1-μm and 2-μm deep, and FIG. 9b shows a profile of the feature measured with an interferometric profilometer (it is noted that because the profilometer does not handle vertical walls very well, what is seen in FIG. 9b for the walls are artifacts of the measurement; the real walls are steeper). Each step is 20-μm wide (laser parameters: 9-mW ofλ32 526-nm light in 0.45-μJ pulses, 470-ns pulse duration, 20-kHz repetition rate, 8-μm focal spot diameter for an on-target intensity of 4.8 ×10⁵ W/cm²). FIG. 9c shows a similar feature, its photograph having been taken with an electron microscope. The depth of these steps are 32 μm and 62 μm, and they are also 20-μm wide (laser parameters: 50-mW ofλ=526-nm light in 2.5-μJ pulses, 450-ns pulse duration, 20-kHz repetition rate, 8-μm focal spot diameter for an on-target intensity of 2.7 ×10⁶ W/cm²). The typical roughness around±0.1 μm, which is comparable to other similar state-of-the-art systems using continuous argon lasers (see www.revise.com). Etching rates ranging between 21 and 1,000 μm³/s were used to produce these particular features, but higher rates are expected if the process is optimized.

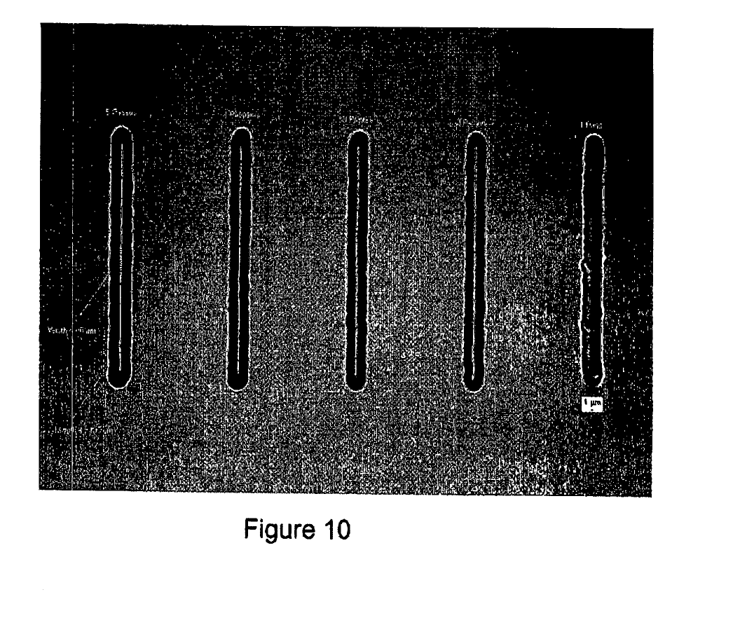

As an example of UV micromachining using a frequency-tripled DPSS laser, FIG. 10 shows several trenches micromachined in a 100-Torr chlorine atmosphere, for a frequency-tripled Nd:YLF laser. The laser parameters were 16-mW ofμ351-nm light in 2-μJ pulses, 100-ns pulse duration, 8-kHz repetition rate, 5-μm focal spot diameter for an on-target intensity of 10⁸ W/cm². The trenches were from 1, 2, 3, 4 and 5 passes on the silicon, respectively, from right to left, with depths ranging from 1 μm to about 4 μm (increasing from right to left), for an etch rate of˜-15 μm³/s for these particular features, chosen low to emphasize the precision-machining regime. Etch rates as high as˜7,100 μm³/s have been observed by the inventors with pulsed UV light. The photographs were taken with an optical microscope.

All the experimental data shown herein (for example all three of FIGS. 8, 9 and 10) were obtained with the same DPSS laser, in its fundamental (IR: 1,053-nm), frequency-doubled (green: 526-nm) and frequency-tripled (UV: 351-nm) wavelengths. It is important to note that with the proper combination of non-linear crystals, it is possible for example to frequency-quadruple (UV: 263-nm), frequency-quintuple (deep UV: 211-nm), and so on the fundamental frequency of solid-state lasers such as the one used here towards smaller and smaller wavelengths for a better control of the lateral and vertical resolution of the micromachining.

There are several advantages of the present Invention over current methods of laser processing of materials, which can be separated in three categories: a) the use of IR to take advantage of the long-absorption-length physics for a faster etch rate, b) the use of solid-state lasers (diode-pumped or flashlamp-pumped, for example) as a cheaper and more reliable alternative to current argon and excimer lasers, and c) the use of solid-state lasers (diode-pumped or flashlamp-pumped, for example) to access multi-wavelength processing, including IR, visible, UV and deep UV.

First, etching rates that are comparable to other state-of-the-art methods using a green CW argon laser are demonstrated with our invention, with the difference that in the present invention, this is obtained with a lower laser power in the IR, so the etch-rate/watt of the present method is greater.

Also, as is apparent from the current experimental data, it is convincingly expected that these etching rate will easily grow to 3-5 times those of other methods by bringing the IR laser power to 10 W, something that is easily within the current commercial DPSS laser technology.

The DPSS lasers currently cost to buy approximately the same per Watt as the argon lasers (and are much cheaper than the excimer lasers). They are also cheaper to operate, with the pumping diodes typically needing replacement every 10,000 hours. This is compared to the argon plasma tube that needs to be replaced typically every 2,500 hours, at a larger cost In parts and down-time. Also, 5-10-W DPSS lasers need only a 110 V, 30A power supply and no cooling water, while an argon laser with the same power requires 208 V, 90 A, 3-phase an 5 gallons/min of cooling water.

Further, DPSS lasers are more reliable (less prone to temperature fluctuations in the room affecting beam pointing, for example), need less warm-up time, and have a smaller footprint (for both the power supply and the laser unit itself) making it easier to integrate in full laser-assisted chemical etching systems.

Finally, the access to multiple wavelengths for machining that is enabled by solid-state lasers makes it possible to optimize the wavelength to the task at is hand: using IR for the large and/or rough features, and switching to frequency-converted output (green, UV, deep-UV) for finer features. Similarly, one can choose the wavelength to best machine the material in question, and/or optimize the effect of the halogen or halogen-containing gas used.

As used herein, the terms “comprises” and “comprising” are to be construed as being inclusive and open ended, and not exclusive. Specifically, when used in this specification including claims, the terms “comprises” and “comprising” and variations thereof mean the specified features, steps or

components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the Invention be defined by all of the embodiments encompassed within the following claims and their equivalents.

Therefore what is claimed is:

1. A method of photo-processing a material, comprising:
illuminating a selected region of a material with a light beam in the presence of a reactive fluid, said light beam having a wavelength in an infrared portion of the electromagnetic spectrum wherein the material has a sufficiently long absorption depth at said infrared wavelength for obtaining volume absorption under the surface of the illuminated region so that the material in a volume under the surface is heated and reacts with said reactive fluid to remove atoms or molecules of said material from said selected region.

2. The method according to claim 1 wherein said light beam is a coherent laser beam.

3. The method according to claim 2 wherein said coherent laser beam is a pulsed laser beam.

4. The method according to claim 2 wherein said coherent laser beam is a continuous wave (cw) laser beam.

5. The method according to claim 3 wherein said pulsed laser beam is produced by one of a diode-pumped solid-state laser and a flashlamp-pumped solid-state laser.

6. The method according to claim 4 wherein said continuous wave laser beam is produced by one of a diode-pumped solid-state laser and a flashlamp-pumped solid-state laser.

7. The method according to claim 1 wherein said reactive fluid is a halogen gas or a halogen containing gas.

8. The method according to claim 1 wherein said material is a semiconductor and said reactive fluid is a halogen gas or a halogen containing gas.

9. The method according to claim 8 wherein said semiconductor is silicon and said halogen gas is chlorine.

10. The method according to claim 8 wherein said infrared wavelength is between about 750 nm to about 3000 nm.

11. The method according to claim 1 wherein said material Is selected from the group consisting of semiconductors, ceramics and polymers.

12. A method of photo-processing of materials, comprising:
selecting a material to be photo-processed and selecting a light source that emits light at a wavelength for which said material has a long absorption depth for obtaining absorption in a volume region under the surface of the material for heating said volume region; and
illuminating a selected region of said material with a beam of the light in the presence of a reactive fluid, wherein said illuminated selected region of said material is heated and reacts with said reactive fluid to remove atoms or molecules of said material from said illuminated region.

13. The method according to claim 12 wherein said light beam is a coherent laser beam.

14. The method according to claim 13 wherein said coherent laser beam is a pulsed laser beam.

15. The method according to claim 13 wherein said coherent laser beam is a continuous wave (cw) laser beam.

16. The method according to claim 14 wherein said pulsed laser beam is produced by one of a diode-pumped solid-state laser and a flashlamp-pumped solid-state laser.

17. The method according to claim 15 wherein said continuous wave laser beam is produced by one of a diode-pumped solid-state laser and a flashlamp-pumped solid-state laser.

18. The method according to claim 12 wherein said reactive fluid is a halogen gas or a halogen containing gas.

19. The method according to claim 12 wherein said material is a semiconductor and said reactive fluid is a halogen gas or a halogen containing gas.

20. The method according to claim 19 wherein said semiconductor is silicon and said halogen gas is chlorine.

21. The method according to claim 19 wherein said infrared wavelength is between about 750 nm to about 3000 nm.

22. The method according to claim 12 wherein said material Is selected from the group consisting of semiconductors, ceramics and polymers.

23. A method of multi-wavelength photo-processing of materials, comprising:
illuminating a region of a material with a light beam having a first wavelength in the presence of a reactive fluid for a pre-selected length of time wherein said illuminated material is heated and reacts with said reactive fluid to remove atoms or molecules of said material from said illuminated region; and
illuminating a region of said material with a fight beam having a second wavelength in the presence of a reactive fluid for a pre-selected length of time wherein said illuminated material is heated and reacts with said reactive fluid to remove atoms or molecules of said material from said illuminated regions, wherein at least one of said first and second wavelengths are selected on the basis of said material having a sufficiently long absorption depth for obtaining absorption in a volume region under the surface of the material for heating said volume region.

24. The method according to claim 23 wherein said at least one of the light beam of said first wavelength and the light beam of the second wavelength are coherent laser beams.

25. The method according to claim 24 wherein said coherent laser beams are pulsed laser beams.

26. The method according to claim 24 wherein said coherent laser beams are continuous wave (cw) laser beam.

27. The method according to claim 25 wherein said pulsed laser beams are produced by one of a diode-pumped solid-state laser and a flashlamp-pumped solid-state laser.

28. The method according to claim 26 wherein said continuous wave laser beams are produced by one of a diode-pumped solid-state laser and a flashlamp-pumped solid-state laser.

29. The method according to claim 24 wherein said at least one of said first and second wavelengths are infrared wavelengths.

30. The method according to claim 29 wherein the other of said at least one of said first and second wavelengths are one of infrared, visible and ultraviolet wavelengths.

31. The method according to claim 23 wherein said reactive fluid is a halogen gas or a halogen containing gas.

32. The method according to claim 23 wherein said material is a semiconductor and said reactive fluid is a halogen gas or a halogen containing gas.

33. The method according to claim 32 wherein said semiconductor is silicon and said halogen gas is chlorine.

34. The method according to claim 32 wherein said infrared wavelength is between about 750 nm to about 3000 nm.

35. The method according to claim 23 wherein said material is selected from the group consisting of semiconductors, ceramics and polymers.
